(19) United States
(12) Patent Application Publication
(10) Pub. No.: US 2024/0306403 A1
(43) Pub. Date: Sep. 12, 2024

(54) STACKED SEMICONDUCTOR DEVICE

(71) Applicant: Micron Technology, Inc., Boise, ID (US)

(72) Inventor: Yeon Seung Jung, Hwaseong (KR)

(21) Appl. No.: 18/426,282

(22) Filed: Jan. 29, 2024

Related U.S. Application Data
(60) Provisional application No. 63/451,085, filed on Mar. 9, 2023.

(51) Int. Cl. H10B 80/00; H01L 25/00; H01L 25/065; H01L 25/18

(52) U.S. Cl. CPC H10B 80/00; H01L 25/0657; H01L 25/18; H01L 25/50; H01L 2225/06513; H01L 2225/06541; H01L 2225/06562; H01L 2225/06586

(57) ABSTRACT

A semiconductor device is provided that can include a substrate and a first and second stack of semiconductor dies coupled to the substrate. The first stack of semiconductor dies and the second stack of semiconductor dies are staggered such that the first stack of semiconductor dies has a first footprint and the second stack of semiconductor dies has a second footprint that partially overlaps the first footprint. The first stack of semiconductor dies and the second stack of semiconductor dies are alternated such that each semiconductor die of the first stack of semiconductor dies is vertically mounted to a respective semiconductor die of the second stack of semiconductor dies. Conductive structures extend between portions of the first and second stacks of semiconductor dies exposed beyond the second footprint and the first footprint, respectively, to electrically couple the semiconductor dies.

### CROSS-REFERENCE TO RELATED APPLICATION(S)

The present application claims priority to U.S. Provisional Patent Application No. 63/451,085, filed Mar. 9, 2023, the disclosure of which is incorporated herein by reference in its entirety.

### TECHNICAL FIELD

The present disclosure generally relates to semiconductor device assemblies and more particularly relates to a stacked semiconductor device.

### BACKGROUND

Microelectronic devices generally have a die (e.g., a chip) that includes integrated circuitry with a high density of very small components. Typically, dies include an array of bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device assembly in accordance with an embodiment of the present technology.

FIG. 2 illustrates a simplified schematic cross-sectional view of a semiconductor device assembly in accordance with an embodiment of the present technology.

FIG. 3 illustrates a simplified schematic cross-sectional view of a semiconductor device assembly in accordance with an embodiment of the present technology.

FIG. 4 illustrates a simplified schematic cross-sectional view of a semiconductor device assembly in accordance with an embodiment of the present technology.

FIG. 5 illustrates a schematic view of a system that includes a semiconductor device assembly configured in accordance with an embodiment of the present technology.

FIG. 6 illustrates a method of fabricating a semiconductor device assembly in accordance with an embodiment of the present technology.

### DETAILED DESCRIPTION

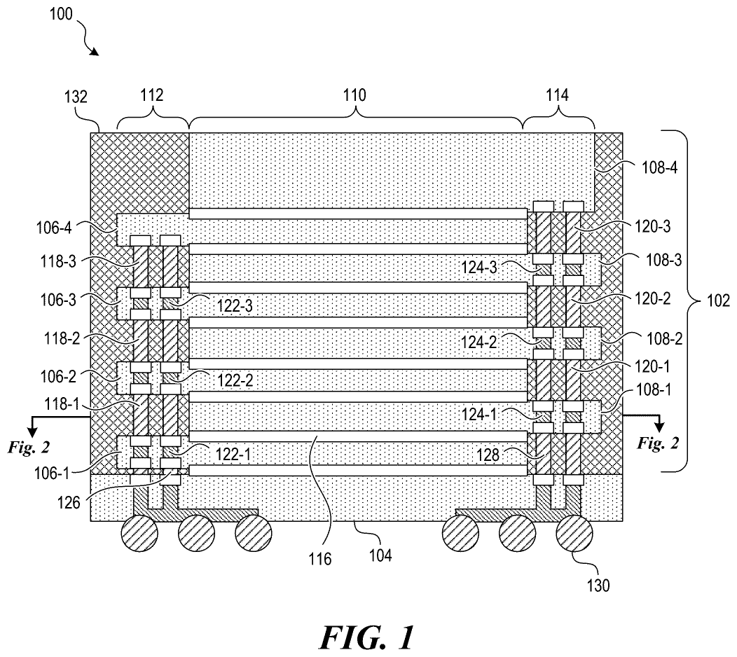

Stacked semiconductor devices are implemented to increase the number of circuit elements on a semiconductor device without simultaneously increasing the device footprint. As the functional requirements for semiconductor devices increase, designers need to implement additional semiconductor dies within a stacked semiconductor device. Consumers are resistant to increasing the maximum allowable height of stacked semiconductor devices (e.g., 720 microns), for example, due to the spatial constraints of the electronic devices in which the stacked semiconductor devices are implemented. To accommodate this requirement, designers have continued to decrease the thickness of semiconductor dies or the space between adjacent semiconductor dies within stacked semiconductor devices. These improvements, however, are reaching their functional limits due to the mechanical and thermal challenges associated with compact semiconductor devices. For example, current manufacturing equipment can struggle to create interconnects below a certain size. Moreover, the high circuit density of compact semiconductor devices can increase the heat production during operation, and thermal regulation components can be difficult to implement within compact semiconductor devices. These factors can make it difficult to operate the semiconductor device below the maximum allowable temperature (e.g., 105 degrees Celsius). Accordingly, additional techniques are needed to implement a compact, stacked semiconductor device, an example of which is illustrated in FIG. 1.

FIG. 1 illustrates a simplified schematic cross-sectional view of a semiconductor device assembly 100 that includes a stack of semiconductor dies 102 (e.g., memory dies) coupled to a substrate 104 (e.g., memory controller, logic die, interposer, printed circuit board (PCB)). For example, the semiconductor device assembly 100 can be a high-bandwidth memory (HBM) device, and thus, the substrate 104 can include a logic die (e.g., a memory controller). The substrate 104 can include a wafer-level or die-level substrate. The stack of semiconductor dies 102 can include two stacks of semiconductor dies that are staggered from one another. For example, semiconductor dies 106 (e.g., 106-1, 106-2, 106-3, 106-4) can be coupled to the substrate 104 such that they have a first footprint. Semiconductor dies 108 (e.g., 108-1, 108-2, 108-3, 108-4) can be coupled to the substrate 104 such that they have a second footprint that partially overlaps the first footprint. Accordingly, the semiconductor dies 106 and the semiconductor dies 108 can have an overlapping portion 110 at which the semiconductor dies 106 and the semiconductor dies 108 overlap, the semiconductor dies 106 can have an exposed portion 112 exposed beyond the second footprint of semiconductor dies 108, and the semiconductor dies 108 can have an exposed portion 114 beyond the first footprint of the semiconductor dies 106.

The semiconductor dies 106 and the semiconductor dies 108 can be stacked in an alternating pattern. For example, each of the semiconductor dies 108 can be mounted to a respective semiconductor die of the semiconductor dies 106. In this way, the semiconductor die 106-1 is mounted to the substrate 104, the semiconductor die 108-1 is mounted to the semiconductor die 106-1, the semiconductor die 106-2 is mounted to the semiconductor die 108-1, and so on. The stack of semiconductor dies 102 can continue in an alternating pattern and finish with the semiconductor die 108-4 being mounted to the semiconductor die 106-4.

In aspects, the semiconductor dies 106 and the semiconductor dies 108 can be directly bonded. For example, conductive material 116 (e.g., copper, gold, silver, aluminum) can be disposed between any two semiconductor dies of the semiconductor dies 106 and the semiconductor dies 108. The conductive material 116 can be disposed at the semiconductor dies 106 and the semiconductor dies 108. In some cases, the conductive material 116 is disposed only at the overlapping portion 110 of the semiconductor dies 106 and the semiconductor dies 108. The conductive material 116 at the semiconductor dies 106 and the semiconductor dies 108 can be annealed to form metal-metal bonds (e.g., through hybrid bonding) coupling the semiconductor dies 106 and the semiconductor dies 108. The conductive material 116 can be disconnected from circuitry at the semiconductor dies 106 and the semiconductor dies 108. In this way, the conductive material 116 may not implement interconnects, but instead, provide a pathway for heat to dissipate from the semiconductor dies 106 and the semiconductor dies 108, thereby increasing the thermal performance of the semiconductor device assembly 100. In embodiments, the semiconductor die 106-1 can be mounted to the substrate 104 through the conductive material 116.

In other cases, the semiconductor dies 106 and the semiconductor dies 108 can be directly bonded through dielectric material (e.g., silicon oxide, silicon nitride, silicon carbide, silicon carbon nitride). For example, dielectric material can be disposed in addition to, or in place of, the conductive material 116. The dielectric material can be disposed at the overlapping portion 110 between adjacent pairs of the semiconductor dies 106 and the semiconductor dies 108. The semiconductor dies 106 and the semiconductor dies 108 can then be fusion-bonded through the dielectric material. In embodiments, the overlapping portion 110 can include the conductive material 116 and the dielectric material disposed laterally along bonding surfaces of the semiconductor dies 106 and the semiconductor dies 108. In this way, the semiconductor dies 106 and the semiconductor dies 108 can be directly bonded through fusion bonds and metal-metal bonds.

In yet another aspect, the semiconductor dies 106 and the semiconductor dies 108 can be directly bonded through an adhesive at the overlapping portion 110. For example, an adhesive can be disposed on bonding surfaces of the semiconductor dies 106 or the semiconductor dies 108. The semiconductor dies 108 can be mounted to the semiconductor dies 106 at the adhesive to directly couple the semiconductor dies 106 and the semiconductor dies 108.

As illustrated, the semiconductor device assembly 100 does not include non-conductive film (NCF) between the semiconductor dies 106 and the semiconductor dies 108. In other semiconductor devices, the semiconductor devices can be stacked with a same footprint, and thus the interconnects may be implemented within an overlapping portion of semiconductor dies. Accordingly, the semiconductor dies are spaced at least by enough distance to implement the vertical interconnects (e.g., more than 10 microns, more than 20 microns, more than 25 microns), which can limit the ability to implement additional semiconductor dies within the semiconductor device. NCF can be used between adjacent semiconductor dies to surround the interconnects implemented between the semiconductor dies and increase the mechanical stability of these devices. NCF can have a low thermal conductivity, which can decrease the thermal performance of these semiconductor devices.

In contrast to these devices, the semiconductor device assembly 100 can implement interconnects outside of the overlapping portion 110, which can reduce the need to space the stack of semiconductor dies 102 (e.g., and the need for NCF). For example, conductive structures 118 can be implemented at the exposed portion 112 between adjacent pairs of the semiconductor dies 106. Specifically, conductive structures 118-1 can be implemented between semiconductor die 106-1 and semiconductor die 106-2, conductive structures 118-2 can be implemented between semiconductor die 106-2 and semiconductor die 106-3, and conductive structures 118-3 can be implemented between semiconductor die 106-3 and semiconductor die 106-4. Similarly, conductive structures 120 can be implemented at the exposed portion 114 between adjacent pairs of the semiconductor dies 108. Specifically, conductive structures 120-1 can be implemented between semiconductor die 108-1 and semiconductor die 108-2, conductive structures 120-2 can be implemented between semiconductor die 108-2 and semiconductor die 108-3, and conductive structures 120-3 can be implemented between semiconductor die 108-3 and semiconductor die 108-4. The conductive structures 118 can extend past the periphery of the semiconductor dies 108. Similarly, the conductive structures 120 can extend past the periphery of the semiconductor dies 106. In aspects, the conductive structures 118 or the conductive structures 120 can include conductive pillars, solder joints, microbumps, or any other appropriate interconnect structure.

The semiconductor dies 106 and the semiconductor dies 108 can include contact pads at which the conductive structures 118 and the conductive structures 120 couple. In this way, the contact pads can be disposed at the exposed portion 112 and the exposed portion 114 of the semiconductor dies 106 and the semiconductor dies 108, respectively. The semiconductor dies 106 and the semiconductor dies 108 can include through-silicon vias (TSVs) 122 (e.g., 122-1, 122-2, 122-3) and TSVs 124 (e.g., 124-1, 124-2, 122-3), respectively, that electrically couple contact pads at opposite surfaces of the semiconductor dies 106 and the semiconductor dies 108. In aspects, semiconductor die 106-4 and semiconductor die 108-4 can include contact pads only on lower surfaces and thus, these semiconductor dies may not include the TSVs 122 or the TSVs 124.

The semiconductor dies 106 and the semiconductor dies 108 can couple with the substrate 104 through interconnects 126 and interconnects 128, respectively. For example, the interconnects 126 can extend between semiconductor die 106-1 and substrate 104, while interconnects 128 can extend between semiconductor die 108-1 and substrate 104. The interconnects 126 and the interconnects 128 can be conductive structures similar to the conductive structures 118 and the conductive structures 120. For instance, the interconnects 128 can include conductive structures that extend from the exposed portion 114 of the semiconductor die 108-1 to the substrate 104. In some implementations, the interconnects 126 can similarly include conductive structures that extend from the exposed portion 112 of the semiconductor die 106-1 to the substrate 104. Alternatively, or additionally, the interconnects 126 can include conductive structures (e.g., solder balls, conductive pillars, microbumps) that extend between the overlapping portion 110 of the semiconductor die 106-1 and the substrate 104.

The substrate 104 can include contact pads at an upper surface, at which the interconnects 126 and the interconnects 128 couple to electrically couple the substrate 104 with the semiconductor dies 106 and the semiconductor dies 108. The substrate 104 can include internal circuitry (e.g., traces, lines, vias, and other connective elements) that connects the contact pads at the upper surface to contact pads at the lower surface. Connective structures 130 (e.g., solder balls) can be disposed at the lower surface to enable connectivity to additional circuit components (e.g., a motherboard). In this way, the connective structures 130 can provide functionality (e.g., power, ground, input/output (I/O) signaling) to the semiconductor dies 106 and the semiconductor dies 108.

Given that the interconnects 122 couple the semiconductor dies 106 and the interconnects 124 couple the semiconductor dies 108, the semiconductor dies 106 and the semiconductor dies 108 may not be directly connected. Instead, the internal circuitry of the substrate 104 can couple the semiconductor dies 106 and the semiconductor dies 108. In some cases, however, the semiconductor dies 106 and the semiconductor dies 108 may be uncoupled from one another. For example, the semiconductor dies 106 and the semiconductor dies 108 can be memory dies, and the substrate 104 can be a logic die that implements separate PHY interfaces for the semiconductor dies 106 and the semiconductor dies 108.

The semiconductor device assembly 100 can further include an encapsulant material 132 (e.g., mold resin compound or the like) that at least partially encapsulates the stack of semiconductor dies 102 and the substrate 104 to prevent electrical contact therewith or provide mechanical strength to the semiconductor device assembly 100.

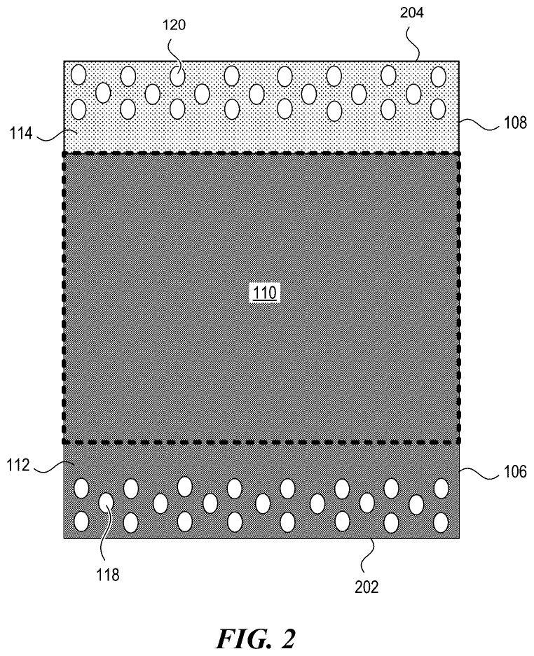

This disclosure now turns to various embodiments to implement a semiconductor device assembly with a staggered stack of semiconductor dies. Specifically, FIG. 2 illustrates a simplified schematic cross-sectional view along the cross-section AA illustrated in FIG. 1. Semiconductor die 106 and semiconductor die 108 are illustrated in a staggered arrangement. For example, the semiconductor die 106 and the semiconductor die 108 overlap at an overlapping portion 110, the semiconductor die 106 extends beyond the semiconductor die 108 at the exposed portion 112, and the semiconductor die 108 extends beyond the semiconductor die 106 at the exposed portion 114. In aspects, the semiconductor die 106 and the semiconductor die 108 can have a same shape and size (e.g., cross-sectional area in the illustrated plane). Conductive structures 118 are implemented at the exposed portion 112, and the conductive structures 120 are implemented at the exposed portion 114.

As illustrated, the exposed portion 112 is implemented at an edge 202 of the semiconductor die 106, and the exposed portion 114 is implemented at an edge 204 of the semiconductor die 108. The edge 204 is parallel with and opposite the first edge 202. For instance, the edge 202 and the edge 204 are on opposite sides of the overlapping portion 110. The exposed portion 112 can equate to less than five percent, 10 percent, 20 percent, 25 percent, or 50 percent of the semiconductor die 106. The conductive structures 118 can be implemented at any portion along the exposed portion 112. The exposed portion 114 can similarly equate to less than five percent, 10 percent, 20 percent, 25 percent, or 50 percent of the semiconductor die 108, and the conductive structures 120 can be implemented at any part of the exposed portion 114.

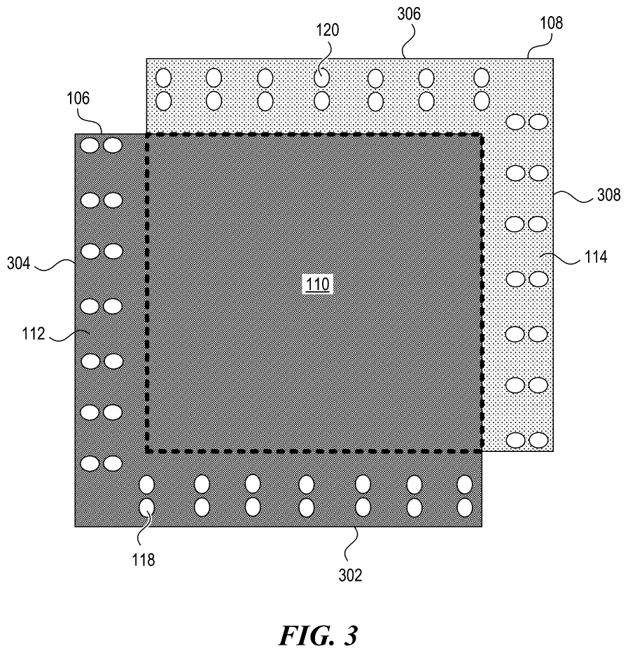

In other implementations, the semiconductor die 106 and the semiconductor die 108 can be staggered in a different direction (e.g., the exposed portions are rotated 90 degrees from one another) or more than one direction, or the semiconductor die 106 and the semiconductor die 108 can have different shapes or sizes to enable different arrangements of exposed portions (e.g., rectangular rather than square). For instance, FIGS. 2 and 3 illustrate simplified schematic cross-sectional views of various arrangements of semiconductor dies that can implement different configurations of exposed portions. The simplified schematic cross-sectional views are taken along a cross-section between two semiconductor dies, similar to the cross-section AA illustrated in FIG. 1. Elements of FIGS. 2 and 3 are labeled similar to the elements of FIG. 1 due to the similarities between these elements. However, a semiconductor device assembly implemented using these semiconductor dies may create a semiconductor device assembly that looks different from the semiconductor device assembly 100 of FIG. 1 (e.g., with additional interconnects, interconnects in different places, or different arrangements of the semiconductor dies).

FIG. 3 illustrates a simplified schematic cross-sectional view of a semiconductor device assembly in accordance with an embodiment of the present technology. Semiconductor die 106 and semiconductor die 108 are illustrated in a staggered arrangement such that the semiconductor dies overlap at the overlapping portion 110, the semiconductor die 106 is exposed beyond the semiconductor die 108 at the exposed portion 112, and the semiconductor die 108 is exposed beyond the semiconductor die 106 at the exposed portion 114. Conductive structures 118 are implemented at the exposed portion 112, and conductive structures 120 are implemented at the exposed portion 114.

As illustrated in FIG. 3, the exposed portion 112 is implemented at an edge 302 of the semiconductor die 106 and at an edge 304 of the semiconductor die 106 perpendicular to the edge 302. In this way, the semiconductor die 106 and the semiconductor die 108 are staggered in more than one direction. Similarly, the exposed portion 114 is implemented at an edge 306 of the semiconductor die 108 parallel and opposite the edge 302 and at an edge 308 of the semiconductor die 108 parallel and opposite the edge 304. As illustrated, the edge 302 and the edge 306 are at opposite sides of the overlapping portion 110. Similarly, the edge 304 and the edge 308 are at opposite sides of the overlapping portion 110.

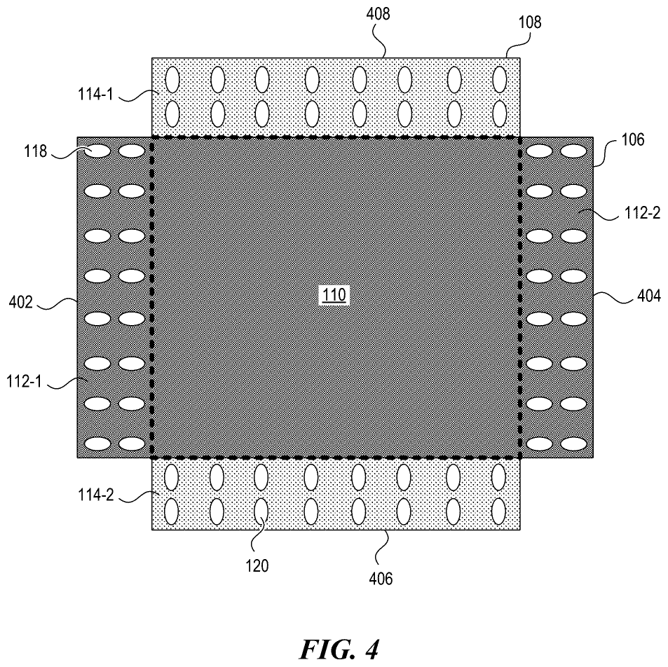

FIG. 4 illustrates a simplified schematic cross-sectional view of a semiconductor device assembly in accordance with another embodiment of the present technology. As illustrated, the semiconductor die 106 and the semiconductor die 108 are non-square such that by stacking the semiconductor die 108 with a 90 degree rotation creates the exposed portion 112 (e.g., 112-1, 112-2) on the semiconductor die 106 and the exposed portion 114 (e.g., 114-1, 114-2) on the semiconductor die 108. The semiconductor die 106 and the semiconductor die 108 overlap in the middle of the semiconductor dies at the overlapping portion 110. The exposed portion 112 includes a first exposed portion 112-1 at edge 402 of the semiconductor die 106 and a second exposed portion 112-2 at edge 404 of the semiconductor die 106 parallel and opposite the edge 402. Similarly, the exposed portion 114 includes a first exposed portion at edge 406 of the semiconductor die 108 perpendicular to the edge 402 and a second exposed portion at edge 408 of the semiconductor die 108 parallel and opposite the edge 406. In this way, the first exposed portion 112-1 and the second exposed portion 112-2 are on opposite sides of the overlapping portion 110, and the first exposed portion 114-1 and the second exposed portion 114-2 are on opposite sides of the overlapping portion. Conductive structures 118 and conductive structures 120 are implemented at the exposed portion 112 and the exposed portion 114, respectively.

Although specific implementations are illustrated with respect to FIGS. 2-4, other implementations are possible. For example, different configurations of the exposed portions and the overlapping portion can be implemented by adjusting the size, shape, or arrangement of the semiconductor dies. Accordingly, it should be appreciated that these are but some of the possible configurations for a stacked semiconductor device.

In accordance with one aspect of the present disclosure, the semiconductor devices illustrated in the assemblies of FIGS. 1-4 could include memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In embodiments, the semiconductor devices can be HBM devices. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

### Example Systems

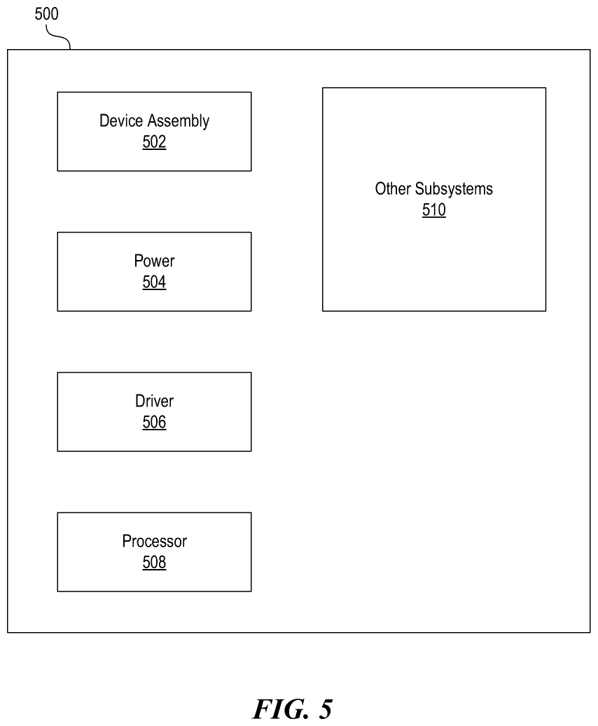

Any one of the semiconductor devices and semiconductor device assemblies described above with reference to FIGS. 1-4 can be incorporated into any of a myriad of larger and/or more complex systems, a representative example of which is system 500 shown schematically in FIG. 5. The system 500 can include a semiconductor device assembly 502 (e.g., a discrete semiconductor device), a power source 504, a driver 506, a processor 508, and/or other subsystems or components 510. The semiconductor device assembly 502 can include features generally similar to those of the semiconductor device assemblies described above with reference to FIGS. 1-4. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances, and other products. Components of the system 500 can be housed in a single unit or distributed over multiple, interconnected units (e.g., through a communications network). The components of the system 500 can also include remote devices and any of a wide variety of computer-readable media.

This disclosure now turns to methods for fabricating semiconductor device assemblies in accordance with one or more embodiments of the present technology. Although illustrated in a particular configuration, operations within any of the methods may be omitted, repeated, or reorganized. Moreover, any of the methods may include additional operations, for example, those detailed in one or more other methods described herein.

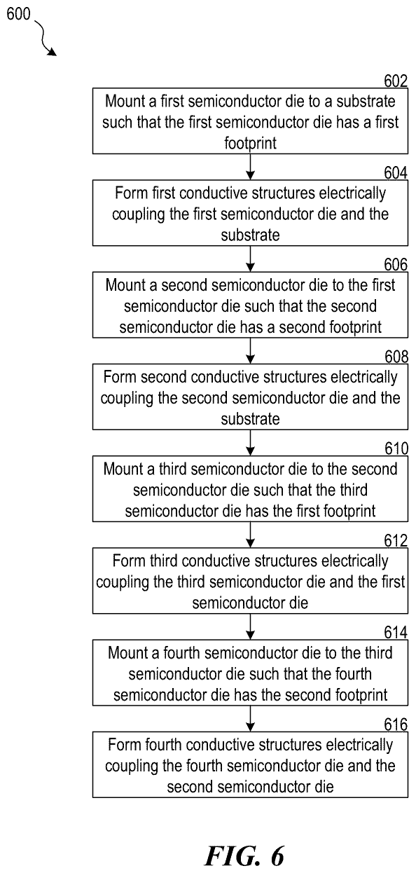

FIG. 6 illustrates a method 600 for fabricating a semiconductor device assembly. At 602, a first semiconductor die is mounted to a substrate such that the first semiconductor die has a first footprint. At 604, first conductive structures that electrically couple the first semiconductor die and the substrate are formed. At 606, a second semiconductor die is mounted to the first semiconductor die such that the second semiconductor die has a second footprint partially overlapping the first footprint. The first and second semiconductor die can be mounted such that a first exposed portion of the first semiconductor die is exposed beyond the second footprint and a second exposed portion of the second semiconductor die is exposed beyond the first footprint. At 608, second conductive structures that electrically couple the second semiconductor die and the substrate are formed. The second conductive structures can extend between the second exposed portion and the substrate.

At 610, a third semiconductor die is mounted to the second semiconductor die such that the third semiconductor die has the first footprint. The third semiconductor die can have a third exposed portion at which the third semiconductor die is exposed beyond the second footprint. At 612, third conductive structures that electrically couple the third semiconductor die and the first semiconductor die are formed. The third conductive structures can extend between the first exposed portion and the third exposed portion. At 614, a fourth semiconductor die is mounted to the third semiconductor die such that the fourth semiconductor die has the second footprint. The fourth semiconductor die can include a fourth exposed portion at which the fourth semiconductor die is exposed beyond the first footprint. At 616, fourth conductive structures that electrically couple the fourth semiconductor die and the second semiconductor die are formed between the second exposed portion and the fourth exposed portion. In doing so, a compact semiconductor device can be assembled.

Specific details of several embodiments of semiconductor devices and associated systems and methods are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical mechanical planarization, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or three-dimensional integration (3DI) applications.

The devices discussed herein, including a memory device, can be formed on a semiconductor substrate or die, such as silicon, germanium, silicon-germanium alloy, gallium arsenide, gallium nitride, etc. In some cases, the substrate is a semiconductor wafer.

In other cases, the substrate can be a silicon-on-insulator (SOI) substrate, such as silicon-on-glass (SOG) or silicon-on-sapphire (SOP), or epitaxial layers of semiconductor materials on another substrate. The conductivity of the substrate, or subregions of the substrate, can be controlled through doping using various chemical species including, but not limited to, phosphorus, boron, or arsenic. Doping can be performed during the initial formation or growth of the substrate, by ion-implantation, or by any other doping means.

The functions described herein can be implemented in hardware, software executed by a processor, firmware, or any combination thereof. Other examples and implementations are within the scope of the disclosure and appended claims. Features implementing functions can also be physically located at various positions, including being distributed such that portions of functions are implemented at different physical locations.

As used herein, including in the claims, “or,” as used in a list of items (for example, a list of items prefaced by a phrase such as “at least one of” or “one or more of”), indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications can be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown or are not described in detail to avoid obscuring other aspects of the technology. In general, it should be understood that various other devices, systems, and methods in addition to those specific embodiments disclosed herein may be within the scope of the present technology.

What is claimed is:

1. A semiconductor device assembly comprising:
a substrate;
a first stack of semiconductor dies coupled to the substrate such that the first stack of semiconductor dies has a first footprint;
a second stack of semiconductor dies coupled to the substrate such that the second stack of semiconductor dies has a second footprint partially overlapping the first footprint,
wherein the first stack of semiconductor dies and the second stack of semiconductor dies are arranged in an alternating pattern such that each of first semiconductor dies in the first stack of semiconductor dies is vertically mounted to and directly bonded with a respective second semiconductor die of second semiconductor dies in the second stack of semiconductor dies, and
wherein the first stack of semiconductor dies and the second stack of semiconductor dies are staggered such that a first exposed portion of each of the first semiconductor dies is exposed beyond the second footprint and a second exposed portion of each of the second semiconductor dies is exposed beyond the first footprint;
first conductive structures extending between adjacent pairs of the first semiconductor dies at the first exposed portion, the first conductive structures electrically coupling the first stack of semiconductor dies; and
second conductive structures extending between adjacent pairs of the second semiconductor dies at the second exposed portion, the second conductive structures electrically coupling the second stack of semiconductor dies.

2. The semiconductor device assembly of claim 1, further comprising:
third conductive structures extending between the substrate and a first bottom semiconductor die of the first semiconductor dies, the third conductive structures electrically coupling the first bottom semiconductor die and the substrate; and
fourth conductive structures extending between the substrate and the second exposed portion of a second bottom semiconductor die of the second semiconductor dies, the fourth conductive structures electrically coupling the second bottom semiconductor die and the substrate.

3. The semiconductor device assembly of claim 1, further comprising:
a first conductive material disposed at least partially over a first surface of each of the first semiconductor dies; and
a second conductive material disposed at least partially over a second surface of each of the second semiconductor dies,
wherein each of the first semiconductor dies is directly bonded with the respective second semiconductor die through a metal-metal bond between the first conductive material and the second conductive material.

4. The semiconductor device assembly of claim 1, further comprising:
a first dielectric material disposed at least partially over a first surface of each of the first semiconductor dies; and
a second dielectric material disposed at least partially over a second surface of each of the second semiconductor dies,
wherein each of the first semiconductor dies is directly bonded with the respective second semiconductor die through a fusion bond between the first dielectric material and the second dielectric material.

5. The semiconductor device assembly of claim 1, wherein:
the first exposed portion is located at a first edge of the first semiconductor dies; and
the second exposed portion is located at a second edge of the second semiconductor dies, the second edge parallel to the first edge.

6. The semiconductor device assembly of claim 5, wherein:
the first exposed portion is further located at a third edge of the first semiconductor dies, the third edge perpendicular to the first edge; and
the second exposed portion is further located at a fourth edge of the second semiconductor dies, the fourth edge parallel to the third edge.

7. The semiconductor device assembly of claim 1, wherein:
the first exposed portion is located at a first edge of the first semiconductor dies; and
the second exposed portion is located at a second edge of the second semiconductor dies, the second edge perpendicular to the first edge.

8. The semiconductor device assembly of claim 1, wherein:
the first exposed portion is further located at a third edge of the first semiconductor dies, the third edge parallel to the first edge; and
the second exposed portion is further located at a fourth edge of the second semiconductor dies, the fourth edge parallel to the second edge.

9. The semiconductor device assembly of claim 1, wherein the first conductive structures or the second conductive structures comprise microbumps.

10. The semiconductor device of assembly claim 1, further comprising:
a first conductive material disposed at least partially over the substrate; and
a second conductive material disposed at least partially over a second surface of a bottom semiconductor die of the second semiconductor dies,
wherein the substrate and the bottom semiconductor die are directly bonded through a metal-metal bond between the first conductive material and the second conductive material.

11. A method of fabricating a semiconductor device assembly comprising:
mounting a first semiconductor die to a substrate such that the first semiconductor die has a first footprint;
forming first conductive structures electrically coupling the first semiconductor die and the substrate;
mounting a second semiconductor die to the first semiconductor die such that the second semiconductor die has a second footprint partially overlapping the first footprint, wherein a first exposed portion of the first semiconductor die is exposed beyond the second footprint and a second exposed portion of the second semiconductor die is exposed beyond the first footprint;
forming second conductive structures electrically coupling the second semiconductor die and the substrate, the second conductive structures extending between the second exposed portion and the substrate;
mounting a third semiconductor die to the second semiconductor die such that the third semiconductor die has the first footprint, wherein a third exposed portion of the third semiconductor die is exposed beyond the second footprint;
forming third conductive structures electrically coupling the third semiconductor die and the first semiconductor die, the third conductive structures extending between the first exposed portion and the third exposed portion;
mounting a fourth semiconductor die to the third semiconductor die such that the fourth semiconductor die has the second footprint, wherein a fourth exposed portion of the fourth semiconductor die is exposed beyond the first footprint; and
forming fourth conductive structures electrically coupling the fourth semiconductor die and the second semiconductor die, the fourth conductive structures extending between the second exposed portion and the fourth exposed portion.

12. The method of claim 11, further comprising:
disposing a first conductive material at least partially over the first semiconductor die; and
disposing a second conductive material at least partially over the second semiconductor die,
wherein mounting the second semiconductor die to the first semiconductor die includes forming a metal-metal bond between the first conductive material and the second conductive material.

13. The method of claim 11, further comprising:
disposing a first dielectric material at least partially over the first semiconductor die; and
disposing a second dielectric material at least partially over the second semiconductor die,
wherein mounting the second semiconductor die to the first semiconductor die includes forming a fusion bond between the first dielectric material and the second dielectric material.

14. The method of claim 11, further comprising:
disposing an adhesive at least partially over the first semiconductor die or the second semiconductor die,
wherein mounting the second semiconductor die to the first semiconductor die includes adhering the second semiconductor die to the first semiconductor die through the adhesive.

15. The method of claim 11, wherein the first conductive structures extend between the first exposed portion and the substrate.

16. The method of claim 11, wherein the first conductive structures, the second conductive structures, the third conductive structures, or the fourth conductive structures comprise microbumps.

17. A semiconductor device assembly comprising:
a substrate;
a first semiconductor die coupled to the substrate such that the first semiconductor die has a first footprint;
a second semiconductor die stacked on the first semiconductor die such that the second semiconductor die has a second footprint different from the first footprint,
wherein a first exposed portion of the first semiconductor die is exposed beyond the second footprint and a second exposed portion of the second semiconductor die is exposed beyond the first footprint;
a third semiconductor die stacked on the second semiconductor die such that the third semiconductor die has the first footprint;
a fourth semiconductor die stacked on the third semiconductor die such that the fourth semiconductor die has the second footprint,
wherein a third exposed portion of the third semiconductor die is exposed beyond the second footprint and a fourth exposed portion of the fourth semiconductor die is exposed beyond the first footprint;
first conductive structures electrically coupling the first semiconductor die and the substrate, the first conductive structures extending between the first semiconductor die and the substrate;
second conductive structures electrically coupling the second semiconductor die and the substrate, the second conductive structures extending between the second exposed portion and the substrate;
third conductive structures electrically coupling the third semiconductor die and the first semiconductor die, the third conductive structures extending between the third exposed portion and the first exposed portion; and
fourth conductive structures electrically coupling the fourth semiconductor die and the second semiconductor die, the fourth conductive structures extending between the fourth exposed portion and the second exposed portion.

18. The semiconductor device assembly of claim 17, further comprising:
a first conductive material disposed at least partially over a first surface of the first semiconductor die; and
a second conductive material disposed at least partially over a second surface of the second semiconductor die,
wherein the first semiconductor die is directly bonded with the second semiconductor die through a metal-metal bond between the first conductive material and the second conductive material.

19. The semiconductor device assembly of claim 17, further comprising:
a first dielectric material disposed at least partially over a first surface of the first semiconductor die; and
a second dielectric material disposed at least partially over a second surface of the second semiconductor die,
wherein the first semiconductor die is directly bonded with the second semiconductor die through a fusion bond between the first dielectric material and the second dielectric material.

20. The semiconductor device assembly of claim 17, wherein;
the substrate comprises a memory controller; and
the first semiconductor die comprises a first memory die; and
the second semiconductor die comprises a second memory die.
